(19) United States
(12) Patent Application Publication
(10) Pub. No.: US 2024/0119202 A1
(43) Pub. Date: Apr. 11, 2024

(54) PREVENTION THROUGH DESIGN ENVIRONMENTAL MATERIAL INTELLIGENCE CENTER

(71) Applicant: University of Florida Research Foundation, Inc., Gainesville, FL (US)

(72) Inventor: Lisa Sundahl Platt, Gainesville, FL (US)

(21) Appl. No.: 18/545,613

(22) Filed: Dec. 19, 2023

Related U.S. Application Data
(63) Continuation of application No. PCT/US2022/073183, filed on Jun. 27, 2022.
(60) Provisional application No. 63/215,676, filed on Jun. 28, 2021.

(51) Int. Cl. G06F 30/27; G06F 16/951; G06F 30/13

(52) U.S. Cl. CPC G06F 30/27; G06F 16/951; G06F 30/13

(57) ABSTRACT

The present disclosure presents systems and methods for building infrastructure and infection prevention data analysis. One such method comprises building contents of an electronic repository of performance metrics related to material pathogen propagation or reduction; assigning, via machine learning, a performance score or grade to a certain infrastructure building material based on the performance metrics associated with the building material; and predicting and outputting, via the machine learning, a risk associated with a building based on its infrastructure building materials, wherein the infrastructure building materials comprises the certain infrastructure building material.

### CROSS-REFERENCE TO RELATED APPLICATION

This application is a continuation of and claims priority to International Application No. PCT/US2022/073183, filed Jun. 27, 2022, which claims the benefit of and priority to U.S. provisional application entitled, “Prevention Through Design Environmental Material Intelligence Center,” having Ser. No. 63/215,676, filed Jun. 28, 2021, each of which is entirely incorporated herein by reference.

### STATEMENT REGARDING FEDERALLY SPONSORED RESEARCH OR DEVELOPMENT

This invention was made whole or in part by funding received from the Angelo Donghia Foundation.

### TECHNICAL FIELD

The present disclosure is generally related to building infrastructure and infection prevention data analysis.

### BACKGROUND

Hospital-onset infections present a significant risk in undermining the health and well-being of many people living in the United States (U.S.) and worldwide. The rise of community-based infections and the growing level of antimicrobial resistance due to factors outside the scope of control of health systems exacerbate this risk. Further, the poor quality control in preventable hospital-onset infections can create a vicious cycle of increased incidence rates in acute care inpatient environments that can be extremely costly to health systems. Accordingly, there is a need for more resources on which building infrastructure materials can help in preventing the spread of infections within high risk environments, such as hospitals.

### SUMMARY

Embodiments of the present disclosure provide systems and methods for building infrastructure and infection prevention data analysis. Such a system comprises at least one processor; and memory configured to communicate with the at least one processor, wherein the memory stores instructions that, in response to execution by the at least one processor, cause the at least one processor to perform operations comprising: obtaining from identified trusted database sources, documents that discuss infrastructure building materials in the context of infection prevention; determining performance metrics for infection prevention from the obtained documents for various building materials; building contents of an electronic repository of performance metrics related to material pathogen propagation or reduction; assigning, via machine learning, a performance score or grade to a certain infrastructure building material based on the performance metrics associated with the building material; and predicting and outputting, via the machine learning, a risk associated with a building based on its infrastructure building materials, wherein the infrastructure building materials comprises the certain infrastructure building material.

Also disclosed herein is a method comprising obtaining, by a computing device from identified trusted database sources, documents that discuss infrastructure building materials in the context of infection prevention; determining, by the computing device, performance metrics for infection prevention from the obtained documents for various building materials; building, by the computing device, contents of an electronic repository of performance metrics related to material pathogen propagation or reduction; assigning, by the computing device via machine learning, a performance score or grade to a certain infrastructure building material based on the performance metrics associated with the building material; and predicting and outputting, by the computing device via the machine learning, a risk associated with a building based on its infrastructure building materials, wherein the infrastructure building materials comprises the certain infrastructure building material.

In one or more aspects, such systems and methods comprise identifying, by the computing device, trusted databases sources relevant to building infrastructure and infection prevention data analysis; storing, by the computing device, the performance metrics for infection prevention as performance data; presenting, via a dashboard interface, stored performance data to a user based on input criteria data provided by the user; finding, by the computing device, patterns within the obtained documents that indicate interior material performance for an infrastructure material; aggregating the performance metrics with Living Building Challenge metrics for the certain infrastructure building material; aggregating the performance metrics with WELL metrics for the certain infrastructure building material; and/or aggregating the performance metrics with LEED certification metrics for the certain infrastructure building material.

In one or more aspects for such systems and/or methods, a WebCrawler component of the computing device assists in identifying the trusted database sources; the obtained documents comprise one or more of peer-reviewed journals, Material Safety and Data Sheets (MSDS), and Technical Performance Specifications; and/or the performance metrics comprise a robustness metric, a recovery metric, a graceful extensibility metric, and a sustained adaptability metric.

Other systems, methods, features, and advantages of the present disclosure will be or become apparent to one with skill in the art upon examination of the following drawings and detailed description. It is intended that all such additional systems, methods, features, and advantages be included within this description and, be within the scope of the present disclosure.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 shows an exemplary system for creating an Infection Prevention through Design Environment Material Intelligence Center (PtD-EMIC) that can be used with deep learning techniques through applied quantitative or qualitative methods in accordance with embodiments of the present disclosure.

FIG. 2 is a flowchart diagram showing an exemplary embodiment of a method for building infrastructure and infection prevention data analysis.

FIG. 3 shows a schematic block diagram of a computing device that can be used to implement various embodiments of the present disclosure.

FIG. 4 shows a table (Table 2) of sustained adaptability criteria and associated performance levels of various infrastructure flooring materials in accordance with the present disclosure.

FIG. 5 shows an exemplary PtD-EMIC Adaptive Neuro-Fuzzy Inference Systems (ANFIS) model structure in accordance with various embodiments of the present disclosure.

FIG. 6 demonstrates that the ANFIS model structure of FIG. 5 can provide accurate outcome predictions in accordance with the present disclosure.

FIGS. 7A-7B validate a prediction of flooring material resilience using model data with independently sourced data.

### DETAILED DESCRIPTION

The present disclosure describes various embodiments of systems, apparatuses, and methods for developing and employing an electronic repository of interior material performance characteristics in connection with preventing the spread of pathogens and hospital acquired infections and performing building infrastructure and infection prevention data analysis.

Hospital Acquired Infection (HAI) incidence rates are caused by both known and unknown factors inside and outside the scope of control of health systems. Pathogen antimicrobial resistance capabilities are continually evolving at exponential rates, and the specific implications and occurrence of increased infectivity in healthcare settings cannot be precisely predicted. These qualities illustrate why infection prevention is itself an emergent quality and illustrate that response resilience inference is appropriate as a methodology for analyzing and measuring the performance capability of a health system infrastructure.

Although strictly community-based infections are the catalyst for a small percentage of infection-related hospital-acquired conditions, many of these incidents are caused by circumstances internal to the hospital (CDC, 2018). In other words, HAI can be a result of endogenous design basis factors integral to the care delivery system itself. For example, interior materials on contact surfaces and other environmental vectors within healthcare settings can serve as viable reservoirs for viral or bacterial transmission (Bin et al., 2015; Deshpande et al., 2017; Kurashige et al., 2016a; J. A. Otter et al., 2016; Suleyman et al., 2018; Weber et al., 2010). Environmental cleaning practices that would support infection control through surface-dwelling pathogen removal in healthcare settings are often sub-optimal (Rutala & Weber, 2013), and research suggests that even 100% treatment area cleaning efficiency provides a limited reduction in the transmission of particularly robust antimicrobial-resistant bacteria (Lei et al., 2017). Furthermore, there can be confusion among Environmental Services staff and nursing personnel in acute care settings regarding who is responsible for cleaning various surfaces and equipment residing in patient treatment areas (Boyce, 2016).

Increasing attention is being given to heating, ventilation, and air conditioning (HVAC) regarding dangerous microbe transmission in healthcare through Air Change per Hour (ACH). However, the incremental benefit to prevent cross-transmission is challenging to establish beyond 12 ACH (Memarzadeh et al., 2010). ACH also does not fully address pathogens left on surfaces after manual cleaning of sterile areas, which can be disturbed and aerosolized by movements of staff members or equipment and then settle onto high touch surfaces leading to hand contamination (Simmons et al., 2018). Human behavior-based infection control interventions, such as clinical staff hand hygiene campaigns, indicate that compliance rates in acute care settings have plateaued at about 50% despite extensive education and adoption campaigns (McGuckin & Govednik, 2015). Given these conditions, it could be reasonable to assume that prolonged and direct exposure to robust pathogens on healthcare surfaces might increase infection contraction potential by immunocompromised or vulnerable patients (Cassone et al., 2017; Suleyman et al., 2018; Yakob et al., 2013).

Thus, improving the resilience of health systems infrastructure can meaningfully contribute to HAI reduction, because, currently, many of these infections are happening within the confines of the healthcare facility itself. However, many investigations into pathogen-resistant substrates, thus far, do not provide enough credible evidence on their own to demonstrate causation between resistant finish or coating material introduction to the built components of the environment of care (EOC) and HAI risk reduction potential (Chyderiotis et al., 2018). Studies on antimicrobial copper, which appears to be the most comprehensively studied pathogen-resistant substrate, have produced some conflicting results based on different environmental or material engineering conditions. For example, in some research at 100% relative humidity, copper surfaces exhibit maximum antimicrobial activity but reduced efficacy of bacterial contact killing at lower humidity levels (Campos et al., 2016). Other studies have observed that higher copper content of alloys, higher temperature, and higher relative humidity increase the antimicrobial efficacy of copper, and specific types of treatments lower corrosion rates, e.g., application of corrosion inhibitors or a thick copper oxide layer decrease bacterial contact killing effectiveness (Grass et al. 2011). Additionally, anti-microbial resistance (AMR) in HAI-causing bacteria seems to be evolving in pathogen resistance to copper toxicity. For example, some strains of bacteria in several different systems have demonstrated an evolved ability that enables them to survive in the presence of a high concentration of copper (Bondarczuk & Piotrowska-Seget, 2013).

An overlooked, but potentially impactful system component to consider in healthcare infection control planning is how we may use existing relevant data repositories related to environmental contextual factors to guide the design for reliable infection prevention infrastructure. Given that there are no current regulations or standards for interior material performance characteristics in connection with preventing hospital acquired infections, an exemplary electronic repository or database of the present disclosure is developed by classifying material performance properties collected through relevant peer-reviewed journals, material specifications, etc. which can reveal patterns in interior material performance that can be used for designing healthcare environments. In accordance with various embodiments, the repository can serve as a platform to which machine learning can be applied for the purpose of gathering information on interior material capability of reducing the propagation of infection causing pathogens within a built environment. Correspondingly, system assessment methodologies can assist in developing and populating the repository and/or can utilize the acquired data to gain a clearer picture of evaluating what types of safe care delivery infrastructure may be needed for an active infection hazard adaptive response. In addition to hospitals and other healthcare facilities, infrastructure within gyms, schools, and other places where people are in close physical contact or are sharing clothes and/or equipment, may be the subject of exemplary methods and systems of the present disclosure.

In certain embodiments, various machine learning techniques may be used with the repository as follows. Decision Trees can be used to specify the shortest sequence of contact surface material design dependent parameters that satisfy the technical performance measures (TPM) of autonomous or semiautonomous pathogen propagation control. A support vector machine can be used to classify specific material technical performance outcomes into specific infection prevention categories and capability for high recall with noisy and sparse data (Ehrentraut, C., Tanushi, H., Dalianis, H., & Tiedemann, J., “Detection of Hospital Acquired Infections in Sparse and Noisy Swedish Patient Records: A Machine Learning Approach using Naïve Bayes, Support Vector Machines and C4.5” (2012)). Natural language processing can also be used to parse linguistic terms related to material pathogen propagation or reduction into fuzzy levels of response capability, which can also be used for heuristic searches.

The Prevention through Design (PtD) construct originated within the context of occupational injury (Prevention through Design | NIOSH | CDC, n.d.). Expanding this model to the context of infection control on high-touch contact surfaces is an actionable way to benefit a building user's safety directly. This approach to science-driven design decision-making for safety-critical settings can improve interior materials' viability and environmental sustainability that comprise the built environment. This approach to applied PtD can also provide a rubric for stakeholders to base demand for safer environments engineered to protect people through innovative, targeted, designed solutions (Schulte et al., 2008).

Recent data indicate that contaminated surfaces in the healthcare environment play an essential role in the endemic and rampant transmission of bacteria resistant to antimicrobial treatments such as Clostridioides difficile (C. diff.) and Methicillin-resistant Staphylococcus aureus (MRSA) that can cause hospital-onset infections (Jonathan A. Otter et al., 2013). C. diff. is currently a prominent endospore in today's health care setting and presents a significant infection risk to vulnerable patients. Symptomatic or asymptomatic patients can shed C. diff. spores and these bacteria can survive for up to five (5) months on inanimate surfaces (Claro et al., 2014). MRSA can survive for up to four (4) months on infected environmental surfaces (Petti et al., 2012). For example, research of MRSA counts on environmental items in constant proximity to vulnerable patients revealed that the surface bioburden of items like overbed tables and bed rails could be relatively high (e.g., 30.6(0-255) colony-forming units (CFU)/100 cm2, for the overbed tables and 159.5 (0-1620) CFU/100 cm2, for the bedside rails) (Kurashige et al., 2016b). Other drug-resistant pathogens can also be targeted, such as carbapenem-resistant Enterobacteriaceae (CRE). As discussed, exemplary systems and methods of the present disclosure can assist in evaluating which types of safe care delivery infrastructure are suitable for an active infection hazard adaptive response.

Consider that it is not as common for viruses to persist within an environment outside a living host as bacteria. However, norovirus, which is one of the leading causes of outbreak-associated gastroenteritis worldwide, can persist on environmental surfaces for up to two months and is easily transferred from the contact surface to humans (Lopman et al., 2012). Additionally, although not considered to be primarily transmitted through surface contact, current bench studies indicate that the SARS-COV-2 has a longer half-life on stainless steel and plastic (van Doremalen et al., 2020), and the transmission of an earlier strain of coronavirus, Middle East Respiratory Syndrome (MERS) indicated that this virus might be transmitted through infective patient viral shedding on surfaces within a treatment environment (Bin et al., 2015; Kim et al., 2016)

As a supplemental air-cleaning measure, Ultraviolet Germicidal Irradiation (UVGI) is sometimes employed within the HVAC system or as a separate unit in reducing the transmission of planktonic airborne bacterial and viral infections in hospitals (USDHHS and CDC, 2017). The use of UVGI devices for terminal cleaning has shown early signs of being a promising adjunctive device for environmental disinfection (Zeber et al., 2018). However, because UVGI is a relatively new technology, there is a dearth of proper research available on the utility of this solution to reduce the overall microbial burden within the EOC (Gardam et al., 2018). Furthermore, sterilization techniques that utilize ultraviolet-light exposure for medical devices have indicated that prolonged exposure can cause some types of synthetic polymer-based surfaces to degrade (Irving et al., 2016; Kowalonek, 2016). However, it is unclear if this structural degradation phenomenon translates to plastics used for applied surfaces in the interior environment. Thus, there is a scarcity in access to building infrastructure and infection prevention resources and analysis.

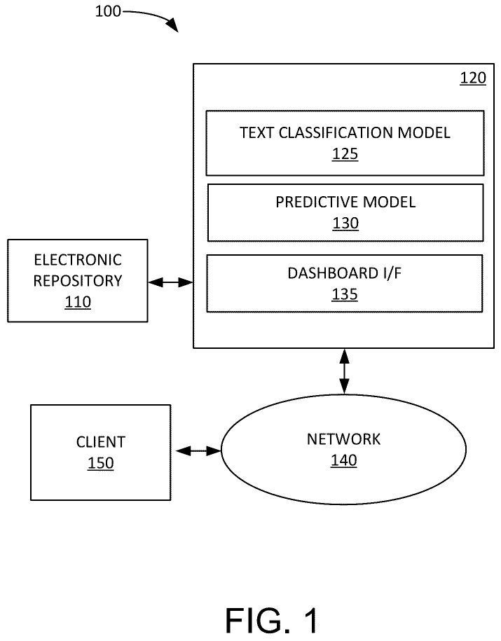

Accordingly, the present disclosure presents exemplary systems and methods for creating an Infection Prevention through Design Environment Material Intelligence Center (PtD-EMIC) that can be used with deep learning techniques through applied quantitative or qualitative methods. Referring to FIG. 1, an exemplary system 100 contains an electronic repository 110, a computer server 120, text classification model 125, a predictive model 130, a dashboard interface 135, a network 140, and a client computer 150. The electronic repository 110 stores information relevant to building infrastructure and infection prevention data analysis. The electronic repository 110 can store both structured and unstructured data. Structured data includes data stored in defined data fields, for example, in a data table. Unstructured data includes raw information, including, for example, computer readable text documents, document images, audio files, video files, and other forms of raw data. Note that some or all of the data in the electronic repository 110 might be analyzed by text mining functionality of the text classification model 125.

For example, material performance properties may be collected from relevant peer-reviewed journals, Material Safety and Data Sheets (MSDS) (that manufacturers issue for their materials), and Technical Performance Specifications related to infection prevention through a resilience engineering taxonomy. In various embodiments, a classification framework may be derived from one that Thomas Seager and David Woods have previously developed. This system of preemptive design qualities focuses on safety preservation & risk avoidance and proposes a hierarchy of technical performance measures (TPM) which include the systems performance criteria: robustness, recovery, graceful extensibility, and sustained adaptability (Seager et al., 2017; Woods, 2015). Accordingly, relevant information on certain building infrastructure materials may be parsed and collected from peer-reviewed journals, data sheets, technical performance specifications, etc. that are maintained in the electronic repository.

According to various embodiments, TPM and key performance indicators (KPI) are prioritized according to EOC safety needs to support user requirements. Such a process may generate a delineation of TPM into discrete functional system criteria. This effort allows for a matrixed approach to identifying material KPI attributes that provides a technical response to design resilience fulfillment. Completed system-level matrices also lend themselves to developing subsystem, component, and system support infrastructure matrices allowing for traceability from high-level to low-level design requirements and vice versa. This matrixed approach to cataloging interior finish performance characteristics can provide the framework for supporting an interactive graphical dashboard interface to understand how to interpret specific interior finish technical performance indicators in the context of occupancy type, evaluate material capabilities to withstand risk and adapt to user needs, apply the material performance analysis outcomes to materiality selection and specification, and create designs that are responsive to human health and well-being. Such an interactive dashboard tool may also provide a complementary platform for facilitating interior material specification alignment with building sustainability and viability benchmarking programs such as Living Building Challenge, WELL, and LEED Certification. This tool will also inform research development and evidence-based design decisions related to human-centered design.

The key performance indicator (KPI) indicative of material resilience can be leveraged as constants on a comparative basis to benchmark the material parameter performance data. This performance data can then be incorporated within a Fuzzy Logic membership function as a basis for parametric evaluation of a proposed resilience metric with an associated fuzzy metric.

According to various embodiments, text mining may use machine learning to examine large amounts of unstructured data to identify a building infrastructure material and find meaningful patterns that indicate interior material performance for the infrastructure material given that there are no building codes related to smart contact surface selection. According to some embodiments, Natural Language Processing may parse text streams into phrases and Named Entity Recognition rules may identify important concepts that are used to augment other structured data elements as predictor variables in models. Accordingly, electronic records can be analyzed to look for patterns (e.g., a particular type or characteristic of a material is associated with antimicrobial qualities). Performance characteristics for infrastructure materials may be stored in data records, such as tables, with entries identifying results of the text mining operations. Moreover, a performance score or grade might be stored in the electronic repository (e.g., after it has been calculated by a predictive model) for a respective infrastructure building material in accordance with the classified specific material technical performance outcomes. In various embodiments, a component of the text classification model 125, such as a WebCrawler component, may identify new database sources from trusted sites on the Internet or other available networks using keyword searches relevant to building infrastructure and infection prevention data analysis.

Used in this context, interior material performance data metrics from the electronic repository 110 could be parsed in the following way: Robustness to contact surface degradation and enhanced maintenance in bacteria removal through environmentally sustainable and safe disinfection practices; Recovery in the automatic response or immediate removal of EOC microbial contaminants with no or minimal human intervention; Graceful Extensibility in PtD strategies capability to respond to infectivity source variability; and Sustained Adaptability capacity to reliable health and safety performance over system's life cycle.

As a means of validating the first (robustness) and fourth (sustained adaptability) criteria, material performance data can be aligned when possible to healthy and sustainable building benchmarking system components such as the following: Living Building Challenge: 4.0 I-12 Responsible Materials; WELL Version 2 Pilot Beta Criteria Concepts/Materials/Feature X15 Optimization: β Contact Reduction: Implement strategies to reduce human contact with respiratory particles and surfaces that may carry pathogens: Part 1 Reduce Respiratory Particle Exposure and Part 2 Address Surface Hand Touch; and LEED v. 4.1 EQ-M.R. Credit; Material Ingredients.

In various embodiments, exemplary PtD-EMIC methods and systems serve as a vehicle for using applied Artificial Intelligence (A.I.) technologies such as machine learning and data mining to reveal common patterns in interior material performance used for designing safety-critical environments like healthcare. Additionally, in various embodiments, a dashboard interface 135 is provided by the computer server 120 to allow for investigators to source material performance data through basic keyword searches of the electronic repository that would inform research development and evidence-based design decisions related to infection prevention. The dashboard interface 135 can also provide a platform for facilitating interior material specification alignment with building sustainability and viability benchmarking program criteria such as: Living Building Challenge, WELL, and LEED Certification.

The computer server 120 includes one or more computer processors, a memory storing the predictive model 130, text classification model 125, and other hardware and software for executing the respective model 125, 130. More specifically, the software may be computer readable instructions, stored on a computer readable media, such as a magnetic, optical, magneto-optical, holographic, integrated circuit, or other form of non-volatile memory. The instructions may be coded, for example, using C, C++, JAVA, SAS or other programming or scripting language. To be executed, the respective computer readable instructions are loaded into RAM associated with the computer server 120.

The predictive model 130 may be a linear regression model, a neural network, a decision tree model, or a collection of decision trees, for example, and combinations thereof. The predictive model 130 may be stored in the memory of the computer server 120, or may be stored in the memory of another computer connected to the network 140 and accessed by the computer server 120 via the network 140. The predictive model 104 preferably takes into account a large number of parameters, such as, for example, characteristics of electronic records (e.g., performance characteristics in addition with other design characteristics). The predictive model 130 may then be used by the computer server 120 to estimate the likelihood that a particular building infrastructure material will reduce the risk of infection of one or more bacterial and/or viral agents, such as by examining decrease rate potential and propagation rate potential with respect to which materials have the tendency to propagate colonizing bacteria forming on their surfaces and what materials have potential to decrease or kill colonizing bacteria on their surfaces or reduce the production of biofilm. Additionally or in the alternative, an exemplary predictive model may estimate the likelihood that a design of a building (having various infrastructure materials) will act in reducing the risk of infection of one more biological agents. For example, in various embodiments, machine learning, such as decision trees, can be deployed to understand what cluster of materials show the greatest promise for the application of contact surfaces (e.g., bed rails) that might reduce the potential for certain types of pathogens on their surfaces.

In various embodiments, the particular data parameters selected for analysis in the training process are determined by using regression analysis or other statistical techniques. The predictive model(s), in various implementation, may include one or more neural networks, decision trees, collections of decision trees, support vector machines, or other systems. Preferably, the predictive model(s) are trained on data and outcomes known about performance characteristics of infrastructure materials. The specific data and outcomes analyzed may vary depending on the desired functionality of the particular predictive model. The particular data parameters selected for analysis in the training process may be determined by using regression analysis and/or other statistical techniques. The parameters can be selected from any of the structured data parameters stored in the present system, whether the parameters were input into the system originally in a structured format or whether they were extracted from previously unstructured text.

Once the text classification model 125 has analyzed the data, the system may determine a quantitative “target variable” that may be used to categorize a collection of performance data into those that exhibit infection reduction behavior and those that do not. For example, a target variable may be the result of a function, which can then be compared against a threshold value. Infrastructure materials that have a target variable value that exceeds the threshold value may be considered to reduce the risk of infection of a particular biological agent, depending on how the function and threshold are defined. The actual predictive model is then created from a collection of observed past performance data metrics and the target variable. In an exemplary embodiment, the predictive model has the form of one or more decision trees. The decision tree(s) may be used to predict the prospect of reducing the spread of infection for the relevant infrastructure materials. For example, if one wanted to find the most infectious-resistant flooring material to use in a build environment, one could do a search using keyword search or decision trees via an exemplary system/method of the present disclosure.

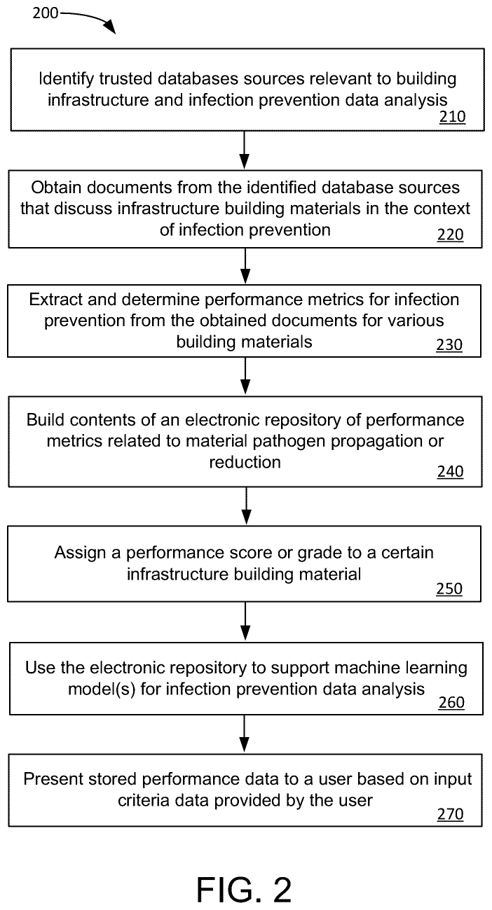

FIG. 2 is a flowchart showing an exemplary embodiment of a method for building infrastructure and infection prevention data analysis. In this embodiment, the process (200) comprises the step of identifying (210) trusted databases sources relevant to building infrastructure and infection prevention data analysis. From the identified database sources, documents may be obtained (220) (e.g., via a WebCrawler) that discuss infrastructure building materials in the context of infection prevention. Next, the process (200) further comprises extracting and determining (230) performance metrics for infection prevention from the obtained documents for various building materials and building (240) contents of an electronic repository of performance metrics related to material pathogen propagation or reduction. Then, a performance score or grade may be assigned (250) to a certain infrastructure building material (e.g., after it has been calculated by a predictive model based on the performance metrics associated with the building material) and may be saved in the electronic repository. Accordingly, electronic repository 110 can support (260) or facilitate the machine learning models, such as, but not limited to, a model that predicts a risk associated with a building based on its building materials. Further, the stored performance data can be presented (270) (e.g., via a dashboard interface 135) to a user based on input criteria data provided by the user.

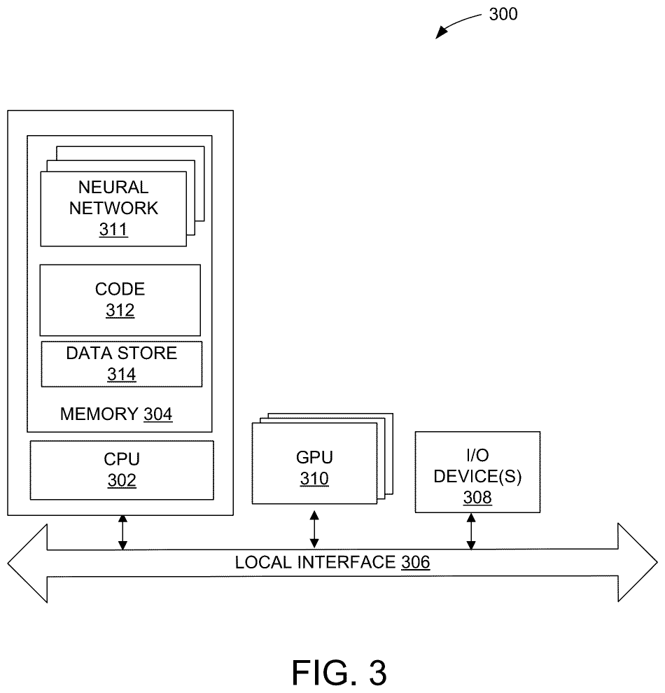

Next, FIG. 3 depicts a schematic block diagram of a computing device 300 that can be used to implement various embodiments of the present disclosure. An exemplary computing device 300 includes at least one processor circuit, for example, having a processor 302 and a memory 304, both of which are coupled to a local interface 306, and one or more input and output (I/O) devices 308. The local interface 306 may comprise, for example, a data bus with an accompanying address/control bus or other bus structure as can be appreciated. The computing device 300 further includes Graphical Processing Unit(s) (GPU) 310 that are coupled to the local interface 306 and may utilize memory 304 and/or may have its own dedicated memory. The CPU and/or GPU(s) can perform various operations such as image enhancement, graphics rendering, image/video processing, recognition (e.g., text recognition, object recognition, feature recognition, etc.), image stabilization, machine learning, filtering, image classification, and any of the various operations described herein.

Stored in the memory 304 are both data and several components that are executable by the processor 302. In particular, stored in the memory 304 and executable by the processor 302 are code for implementing one or more neural networks 311 (e.g., artificial and/or convolutional neural network models) and code 312 for using the neural network models 311 for building infrastructure and infection prevention data analysis. Also stored in the memory 304 may be a data store 314 and other data. The data store 314 can include an electronic repository or database relevant to computable records of building infrastructure and infection prevention data analysis. In addition, an operating system may be stored in the memory 304 and executable by the processor 302. The I/O devices 308 may include input devices, for example but not limited to, a keyboard, mouse, etc. Furthermore, the I/O devices 308 may also include output devices, for example but not limited to, a printer, display, etc.

For a proof-of-concept demonstration of the PtD-EMIC system, evaluation of materiality resilience is constrained to standard flooring types often specified for high-risk treatment environments. The property of “Graceful Extensibility” is assumed since any of these flooring types would be appropriate for use in patient treatment settings. In this context, the property of “Robustness” is characterized by estimated Material Life Years derived from the product warranty. A “Proportionate Robustness” factor can be derived from the total of all relevant Material Life Years. Table 1 (below) delineates the flooring material types and associated metrics used for this analysis. (Note: Warranty information for products was obtained from technical product specifications and The Tile Council of North America https://www.tcnatile.com/).

TABLE 1

| | | *Material | |
|---|---|---|---|
| | Material | Lifetime | Proportionate |
| Material Type | Code | Yrs. | Robustness |
| Ceramic Tile, Porcelain, epoxy grout | 10 | 75 | 0.34 |
| Terrazzo, thin-set epoxy resin, | 20 | 75 | 0.34 |
| acrylic sealant | | | |
| Linoleum sheet, urethane sealant | 30 | 30 | 0.14 |
| Luxury Vinyl Tile, urethane sealant | 40 | 8 | 0.04 |
| Vinyl Composition Tile | 50 | 5 | 0.02 |
| (VCT) (Armstrong) | | | |
| Vinyl, sheet, heat welded, | 60 | 10 | 0.05 |
| urethane sealant | | | |
| Rubber, sheet, urethane sealant | 70 | 15 | 0.07 |
| Combined Total of Possible | | 218 | |
| Flooring Material Life Years | | | |

The material “Recovery” criteria require a more arbitrary performance classification. Certain healthcare contact surface materials such as ceramics and certain types of terrazzo (e.g., cementitious rather than epoxy) are characterized by ionic bonding of composites that have demonstrated resistance to degradation under repeated UV-C disinfection (Dancer, 2014; Rockett, 2019; Simmons et al., 2018). However, since UV-C is still a relatively new technology, there is a shortage of research available on the utility of this solution in reducing the overall microbial burden within the EOC and its effect on typical materials used for health system contact surfaces. A recent study on UV-C degradation for polymers and polymer matrix composites (Lu et al., 2018) can be used to establish the possible degradation level of polymer-based flooring materials used in healthcare settings and thus a Recovery baseline. This study demonstrates that for polymer-based materials, there is a maximum of one thousand (1000) hours to significant degradation. When considered in an annual temporal frame, these results suggest there could be a yearly degradation percentage for specific materials. For polymer-based materials, the degradation level could be up to eighty-nine percent (PA=89%), and ionic bonded materials resistant to UV degradation, such as ceramic tile and cementitious terrazzo of zero percent (PB=0%). Using the complement of material degradation as a hypothetical proportion for flooring material recovery would set the level of polymer-based materials at approximately eleven percent (PA′=11%) and the recovery of ionic bonded materials at one hundred (PB′=100%).

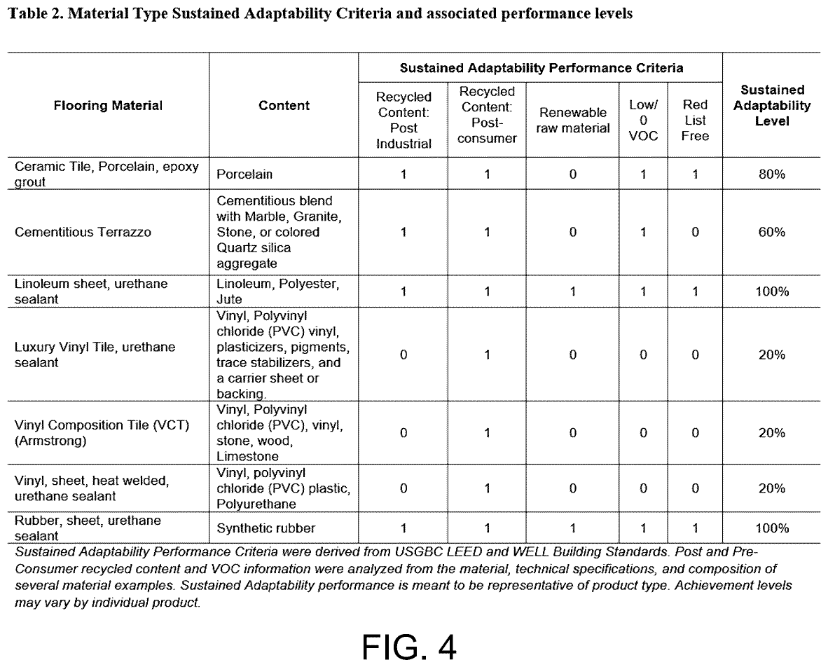

Material Sustained Adaptability or “Sustainability” can be exemplified by characteristics common to third-party material benchmarking criteria like the US Green Building Council's LEED rating system (https://www.usgbc.org/leed) or the International WELL Building Institute Standard's concepts (https://dev-wellv2.wellcertified.com/wellv2/en/concepts). A taxonomy can be created of individual material metrics for Sustained Adaptability Performance Criteria. This data frame can illustrate whether a material satisfied (1) or did not satisfy (0) Sustained Adaptability Levels based on the proportion of criteria that a specific material satisfied (refer to Table 2 (FIG. 4)).

In an exemplary implementation, the architecture of the PtD-EMIC instrument is based on two Fuzzy Inference Systems (FIS) methods, Sugeno Zeroth Order and Adaptive Neuro-Fuzzy Inference Systems or “ANFIS.” In general, Fuzzy Inference Systems (FIS) combine variable Fuzzy Set membership functions with Fuzzy Control rules to derive a crisp system's output (Bai & Wang, 2006). A Fuzzy “universe of discourse” (NX) represents a series of linguistic variables that define the fuzzy functional qualities of a system or subsystem that embody a definition of “performance” that is vague yet context-specific (Dubois, 1980). Considering that the concepts of “resilience” are difficult to describe effectively by classical mathematical equations or crisp performance sets makes this approach viable for this analysis instrument.

A Fuzzy-singleton-style/Zeroth order Sugeno style FIS takes the form of a constant or linear equation (Yulianto et al., 2017). Linear models of system characteristics are constructed around selected operating points and combined to attain the overall system model (Cococcioni et al., 2002). The form of the equation a Zeroth-Order Sugeno model takes is as follows (Yulianto et al., 2017):

IF(x1isA1)°(x2isA2)°(x3isA3)° . . . °(xNis AN)THEN z=k

The first factor is the fuzzy set as antecedent, where ° is the fuzzy operator (AND or OR), x is a constant, and Aᵢ is the firing strengths or weight of each factor of x. The key performance indicator (KPI) indicative of material resilience can be leveraged as constants on a comparative basis to benchmark the material parameter performance data. This performance data can then be incorporated within a Fuzzy Logic membership function as a basis for parametric evaluation of a proposed resilience metric with an associated fuzzy metric. Using this approach within the universe of discourse (NX) of treatment environment materiality resilience, our IF-THEN is formulated as:
IF a contact surface material's properties include those that function at μ_{α} (Robustness) at a concentration of “x” AND μ_{β} (Recovery) at a concentration of “y,” AND μ_{γ} (Sustainability) at a concentration of “z” THEN “r”=an overall material Prevention through Design (PtD) Resilience factor of k.

The “concentration” parameter can serve as a weighted variable for determining the importance of each KPI parameter. Due to its structure, Fuzzy Logic has a unique ability as a mathematical operator to interpret linguistic variables quantitatively. This capability allows for the accrual of potentially valuable heuristic knowledge from various process subject matter experts to assign concentration or importance levels based on determined weighting factors such as “Low Importance (25% weight),” “Some Importance (50% weight),” “Moderate Importance (75% weight)”, “High Importance (100%).” For the proof-of-concept demonstration of this instrument, an arbitrary weight of 75%—Moderate Importance was used for each parameter.

For example: Material Type 10μₓ: (0.34×0.75)(1×0.75)+(0.8×0.75)/(0.75+0.75+0.75))/100=0.013.

A data frame that maps the flooring PtD-Resilience universe of discourse using fuzzy levels of KPI performance parameters for each material type can then be constructed (as illustrated by Table 3 below) and used for analysis by an ANFIS model.

TABLE 3

| | KPI Variables | | | |
|---|---|---|---|---|
| Material | Robust | Recovery | Sustain | PtD-Resilience |
| 10 | 0.34 | 1.000 | 0.80 | 0.013 |
| 20 | 0.34 | 1.000 | 0.60 | 0.012 |
| 30 | 0.14 | 0.114 | 1.00 | 0.005 |
| 40 | 0.04 | 0.114 | 0.20 | 0.002 |
| 50 | 0.02 | 0.114 | 0.20 | 0.002 |
| 60 | 0.05 | 0.114 | 0.20 | 0.002 |
| 70 | 0.07 | 0.114 | 1.00 | 0.005 |

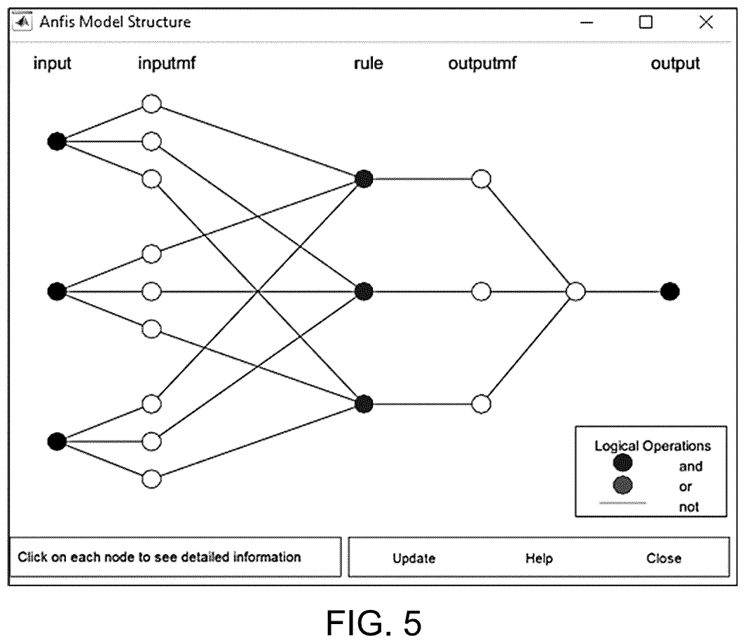

Adaptive Neuro-Fuzzy Inference Systems or ANFIS employs the Sugeno Fuzzy Logic architecture to map combined variable predictive outcomes (Jang et al., 1997). ANFIS is a data-driven technique based on a neural net structure that can be utilized to solve function approximation problems (Karim et al., 2019). This type of Sugeno fuzzy inference systems (FIS) architecture uses a combination of least-squares and backpropagation gradient descent methods, along with hybrid learning algorithms to identify the membership function parameters of a series of fuzzy IF-THEN rules based on a single output or singleton (Ho & Tsai, 2011). ANFIS has demonstrated superiority in predictive accuracy over traditional inferential statistical methods and precedent success in predicting object performance metrics that are vague but not unspecific (Mokarram, 2019). The structure of the ANFIS model used for this analysis is illustrated in FIG. 5.

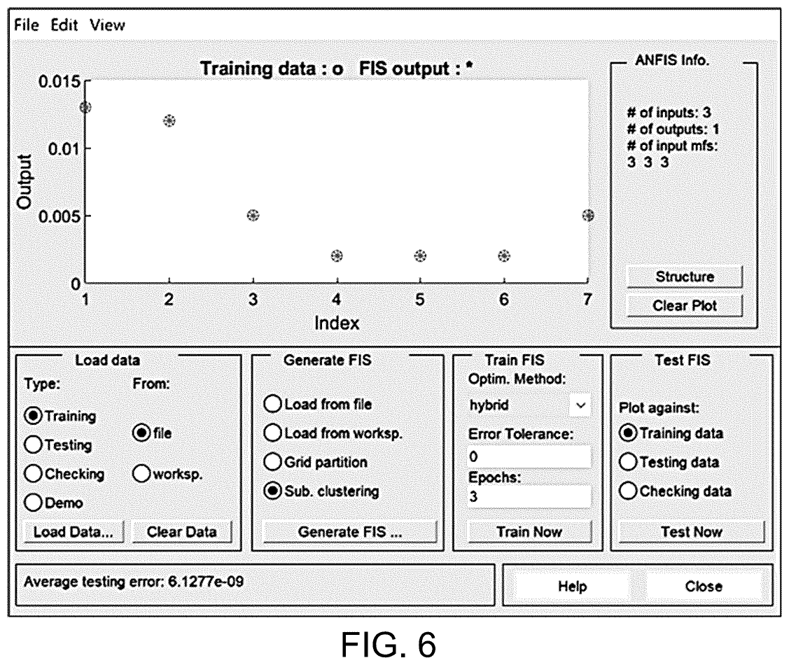

Using MathWorks MatLab Fuzzy Logic Designer, the Integrative PtD-Resilience Environmental Material μₓ data frame can be loaded as a test set into an ANFIS model to determine the accuracy of KPI parameters in predicting Pt-D-Resilience Outcomes. FIG. 6 suggests the accuracy of the Fuzzy Hierarchical Model is adequate for accurate outcome prediction with a Root Mean Square Error (RMSE) of 6.1277 e−09.

The sparse data set validated the ANFIS model prediction accuracy through two methods. The first was to use the MatLab Fuzzy Logic Designer program FIS checking data option. The results of this checking data function indicated the model is adequate for accurate outcome prediction with a Root Mean Square Error (RMSE) of 2.156 e−18. The second was the use of Pearson's Correlation (r) to evaluate if the experimental outcomes of ANFIS were reflected in a high correlation between criterion (Resilience) and predictor (KPI) variables. This approach has precedent use in validating the accuracy of ANFIS Models (Ahmed & Shah, 2017; Esmaeili et al., 2015). The results indicated a high correlation between the predictor KPI of Robustness and Recovery and the criterion of Resilience (e.g., r=0.99; r=0.95, respectively) and a moderate correlation between Sustainability and Resilience (e.g., r=0.52) across all variables. These results suggest alignment in both validation method outcomes of the ANFIS PtD-EMIC model.

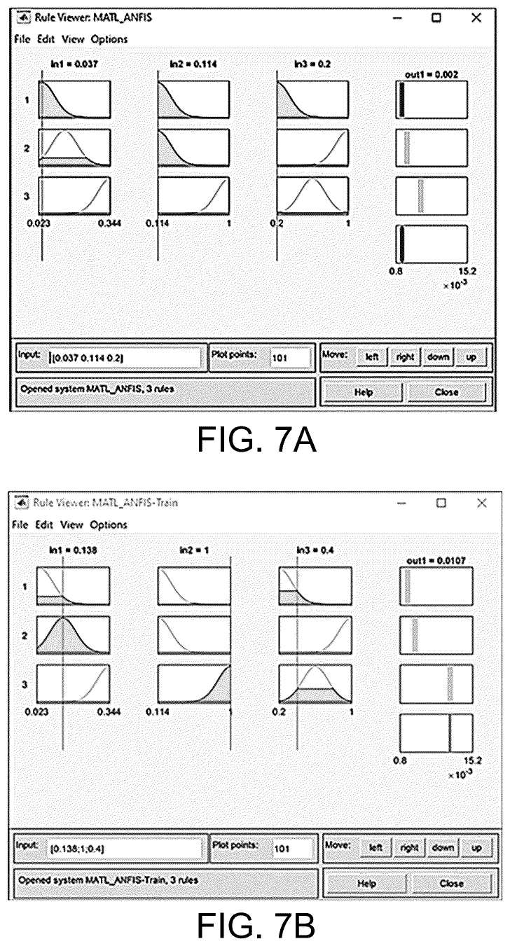

The analysis results suggest that using ANFIS on the proof-of-concept PtD-EMIC data frame accurately predicts the infection prevention and health safety resilience levels of healthcare flooring materials near actual values. FIGS. 7A-7B demonstrate how this model's decision rule algorithms can be used to predict resilience outcomes using data within the test set (FIG. 7B) and with independently sourced information gleaned from healthcare contact surface materials (FIG. 7A).

The ability to predict interior materials' infection control resilience potential illustrates the benefits of the PtD-EMIC Computational Design instrument for healthcare environment research and healthcare design practice. Expansions of applications using neuro networks and fuzzy logic through ANFIS for decision support tools for optimizing resilience response can also contribute valuable insight into adaptive capacity control mechanisms of healthcare environment of care materials to reduce pathogen spread and respond to enhanced disinfection. Instruments such as the PtD-EMIC can provide a viable and unique method for designing multifactorial systems with mutable and complex safety needs like healthcare settings.

Certain embodiments of the present disclosure can be implemented in hardware, software, firmware, or a combination thereof. If implemented in software, the building infrastructure and infection prevention data analysis logic or functionality are implemented in software or firmware that is stored in a memory and that is executed by a suitable instruction execution system. If implemented in hardware, the building infrastructure and infection prevention data analysis logic or functionality can be implemented with any or a combination of the following technologies, which are all well known in the art: discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

It should be emphasized that the above-described embodiments are merely possible examples of implementations, merely set forth for a clear understanding of the principles of the present disclosure. Many variations and modifications may be made to the above-described embodiment(s) without departing substantially from the principles of the present disclosure. All such modifications and variations are intended to be included herein within the scope of this disclosure.

Therefore, at least the following is claimed:

1. A method of automated building infrastructure and infection prevention data analysis comprising:
building, by a computing device from identified trusted database sources, contents of an electronic repository of performance metrics related to material pathogen propagation or reduction;
assigning, by the computing device via machine learning, a performance score or grade to a certain infrastructure building material based on the performance metrics associated with the building material; and
predicting and outputting, by the computing device via the machine learning, a risk associated with a building based on its infrastructure building materials, wherein the infrastructure building materials comprises the certain infrastructure building material.

2. The method of claim 1, further comprising identifying, by the computing device, trusted databases sources relevant to building infrastructure and infection prevention data analysis.

3. The method of claim 1, wherein a WebCrawler component of the computing device assists in identifying the trusted database sources.

4. The method of claim 1, further comprising:
storing, by the computing device, the performance metrics for infection prevention as performance data; and
presenting, via a dashboard interface, stored performance data to a user based on input criteria data provided by the user.

5. The method of claim 1, further comprising
obtaining, by the computing device from the identified trusted database sources, documents that discuss infrastructure building materials in the context of infection prevention; and
determining, by the computing device, the performance metrics for infection prevention from the obtained documents for various building materials,
wherein the obtained documents comprise one or more of peer-reviewed journals, Material Safety and Data Sheets (MSDS), and Technical Performance Specifications.

6. The method of claim 1, further comprising finding, by the computing device, patterns within the obtained documents that indicate interior material performance for an infrastructure material.

7. The method of claim 1, wherein the performance metrics comprise a robustness metric, a recovery metric, a graceful extensibility metric, and a sustained adaptability metric.

8. The method of claim 1, further comprising aggregating the performance metrics with Living Building Challenge metrics for the certain infrastructure building material.

9. The method of claim 1, further comprising aggregating the performance metrics with WELL metrics for the certain infrastructure building material.

10. The method of claim 1, further comprising aggregating the performance metrics with LEED certification metrics for the certain infrastructure building material.

11. A system of method of automated building infrastructure and infection prevention data analysis comprising:
at least one processor; and
memory configured to communicate with the at least one processor, wherein the memory stores instructions that, in response to execution by the at least one processor, cause the at least one processor to perform operations comprising:
building contents of an electronic repository of performance metrics related to material pathogen propagation or reduction from identified trusted database sources;
assigning, via machine learning, a performance score or grade to a certain infrastructure building material based on the performance metrics associated with the building material; and
predicting and outputting, via the machine learning, a risk associated with a building based on its infrastructure building materials, wherein the infrastructure building materials comprises the certain infrastructure building material.

12. The system of claim 11, wherein the operations further comprise identifying trusted databases sources relevant to building infrastructure and infection prevention data analysis.

13. The system of claim 11, wherein a WebCrawler component of the computing device assists in identifying the trusted database sources.

14. The system of claim 11, wherein the operations further comprise:
storing the performance metrics for infection prevention as performance data; and
presenting, via a dashboard interface, stored performance data to a user based on input criteria data provided by the user.

15. The system of claim 11, wherein the operations further comprise:
obtaining, from the identified trusted database sources, documents that discuss infrastructure building materials in the context of infection prevention;
determining the performance metrics for infection prevention from the obtained documents for various building materials,
wherein the obtained documents comprise one or more of peer-reviewed journals, Material Safety and Data Sheets (MSDS), and Technical Performance Specifications.

16. The system of claim 11, wherein the operations further comprise finding patterns within the obtained documents that indicate interior material performance for an infrastructure material.

17. The system of claim 11, wherein the performance metrics comprise a robustness metric, a recovery metric, a graceful extensibility metric, and a sustained adaptability metric.

18. The system of claim 11, wherein the operations further comprise aggregating the performance metrics with Living Building Challenge metrics for the certain infrastructure building material.

19. The system of claim 11, wherein the operations further comprise aggregating the performance metrics with WELL metrics for the certain infrastructure building material.

20. The system of claim 11, wherein the operations further comprise aggregating the performance metrics with LEED certification metrics for the certain infrastructure building material.
